(19) United States
(12) Patent Application Publication
(10) Pub. No.: US 2013/0108956 A1
(43) Pub. Date: May 2, 2013

(54) NANOCOMPOSITE POSITIVE PHOTOSENSITIVE COMPOSITION AND USE THEREOF

(71) Applicants: Ping-Hung LU, Bridgewater, NJ (US); Chunwei CHEN, Bridgewater, NJ (US); Stephen MEYER, Saylorsburg, PA (US)

(72) Inventors: Ping-Hung LU, Bridgewater, NJ (US); Chunwei CHEN, Bridgewater, NJ (US); Stephen MEYER, Saylorsburg, PA (US)

(73) Assignee: AZ ELECTRONIC MATERIALS USA CORP., SOMERVILLE, NJ (US)

(21) Appl. No.: 13/286,712

(22) Filed: Nov. 1, 2011

(51) Int. Cl. G03F 7/20; G03F 7/004; B82Y 30/00

(52) U.S. Cl. 430/270.1; 430/323; 977/773

(57) ABSTRACT

The present invention relates to a positive photosensitive composition suitable for image-wise exposure and development as a positive photoresist comprising a positive photoresist composition and an inorganic particle material having an average particle size equal or greater than 10 nanometers, wherein the thickness of the photoresist coating film is less than 5 microns. The positive photoresist composition can be selected from (1) a composition comprising (i) a film-forming resin having acid labile groups, and (ii) a photoacid generator, or (2) a composition comprising (i) a film-forming novolak resin, and (ii) a photoactive compound, or (3) a composition comprising (i) a film-forming resin, (ii) a photoacid generator, and (iii) a dissolution inhibitor. The invention also relates to a process of forming an image using the novel photosensitive composition.

### FIELD OF INVENTION

The present invention relates to a novel photosensitive composition suitable for image-wise exposure and development as a positive photoresist comprising a positive photoresist composition and an inorganic particle material having an average particle size equal or smaller than 100 nanometers, wherein the thickness of the photoresist coating film is less than 5 microns. The invention also relates to a process of forming a pattern.

### DESCRIPTION

Photoresist compositions are used in lithographic processes for making miniaturized electronic components such as in the fabrication of computer chips, integrated circuits, light emitting diodes, display device, etc. Generally, in these processes, a coating of film of a photoresist composition is first applied to a substrate material, and the coated substrate is then baked to evaporate any solvent in the photoresist composition and to fix the coating onto the substrate. The baked coated surface of the substrate is next subjected to an image-wise exposure to radiation. This radiation exposure causes a chemical transformation in the exposed areas of the coated surface. Visible light, ultraviolet (UV) light, electron beam and X-ray radiant energy are radiation types commonly used today in lithographic processes. After this image-wise exposure, the coated substrate is treated with a developer solution to dissolve and remove either the radiation-exposed or the unexposed areas of the coated surface of the substrate.

When positive-working photoresist compositions are exposed image-wise to radiation, those areas of the photoresist composition exposed to the radiation become more soluble to the developer solution while those areas not exposed remain relatively insoluble to the developer solution. Thus, treatment of an exposed positive-working photoresist with the developer causes removal of the exposed areas of the coating and the creation of a positive image in the photoresist coating. A desired portion of the underlying substrate surface is uncovered.

After this development operation, the now partially unprotected substrate may be treated with a substrate-etchant solution, plasma gases, or have metal or metal composites deposited in the spaces of the substrate where the photoresist coating was removed during development. The areas of the substrate where the photoresist coating still remains are protected. Later, the remaining areas of the photoresist coating may be removed during a stripping operation, leaving a patterned substrate surface. In some instances, it is desirable to heat treat the remaining photoresist layer, after the development step and before the etching step, to increase its adhesion to the underlying substrate.

Positive-acting photoresists comprising novolak resins and quinone-diazide compounds as photoactive compounds are well known in the art. Novolak resins are typically produced by condensing formaldehyde and one or more multi-substituted phenols, in the presence of an acid catalyst, such as oxalic acid. Photoactive compounds are generally obtained by reacting multihydroxyphenolic compounds with naphthoquinone diazide acids or their derivatives. Novolaks may also be reacted with quinine diazides and combined with a polymer.

Additives, such as surfactants, are often added to a photoresist composition to improve the coating uniformity of the photoresist film where the film thickness is less than 5 microns, especially to remove striations within the film. Various types of surfactants are added typically at levels ranging from about 5 ppm to about 200 ppm.

In the manufacture of Light emitting diodes (LED) creation of surface texture (roughening) is employed to improve light extraction from the high index LED to the outside. The creation of surface texture or roughening (undulations on the surface) improves the chances of light making it out of the high index of refraction medium by allowing the exiting light more surfaces at which the angle of the light with the surface is such that total internal reflection does not occur. Typically, three methods are employed to accomplish this as follows: roughening of the surface of the LED caused chemically or mechanically; patterning of the substrate by using lithography and a wet or reactive ion etching of an underlying chemically vapor deposited oxide to create bumps which are 1-5 microns in size with a 5-10 micron pitch; and, photonic crystals are made at the surface of an LED and are made by a combination of lithography and reactive ion etching to form holes smaller than 1 micron with a periodic or semi periodic pattern.

A specific example is the manufacture of PSS (patterned sapphire substrate) light emitting diodes (LED) consisting of a dense array of bumps that need to be patterned using a positive photoresist coated on a CVD (chemical vapor deposited) layer of silicon oxide. Typically, the photoresist is used to create the CVD hard mask which is then used to transfer the pattern into the underlying sapphire substrate, causing roughening. Other substrates are patterned in this way such as Si, SiC and GaN.

The applicants of the present invention have unexpectedly found that the addition of nanoparticles to a positive photoresist can provide a significant increase in the plasma etch resistance towards chlorine based plasma, which is used to etch a sapphire substrate. The photoresists containing nanoparticles which increase the plasma etch resistance can be used in films thinner than 5 microns to increase the throughput for the manufacture of PSS LED (light emitting diodes) and reduce the cost of manufacturing by eliminating the need for CVD oxide hard masks. Similarly, the patterning of substrates such as sapphire, GaN, Si and SiC, and the manufacture of photonic crystals would also see an increase in throughput by eliminating the need for a chemical vapor deposition of silicon dioxide as a separate step.

### SUMMARY OF THE INVENTION

The present invention relates to a photosensitive composition suitable for image-wise exposure and development comprising a positive photoresist composition and an inorganic particle material having an average particle size equal to or smaller than 100 nanometers, wherein the thickness of the photoresist coating film is less than 5 microns. The positive photoresist composition can be selected from (1) a composition comprising (i) a film-forming resin having acid labile groups, and (ii) a photoacid generator, or (2) a composition comprising (i) a film-forming novolak resin, and (ii) a photoactive compound, or (3) a composition comprising (i) a film-forming resin, (ii) a photoacid generator, and (iii) a dissolution inhibitor. The present invention also relates to a process for using the novel composition for forming an image on a substrate. The imaged substrate can be further dry etched using a gas.

### DESCRIPTION OF THE INVENTION

The present invention relates to a novel photosensitive or photoresist composition suitable for image-wise exposure and development as a positive photoresist comprising a standard positive photoresist composition and an inorganic particle material having an average particle size less than 100 nanometers, wherein the thickness of the photoresist coating film is less than 5 microns. The standard positive photoresist composition can be selected from (1) a composition comprising (i) a film-forming resin having acid labile groups, and (ii) a photoacid generator, or (2) a composition comprising (i) a film-forming novolak resin, and (ii) a photoactive compound, or (3) a composition comprising (i) a film-forming resin, (ii) a photoacid generator, and (iii) a dissolution inhibitor.

Standard photoresist compositions suitable for image-wise exposure and development as a positive photoresist are known and can be used herein.

Resin binders, such as novolaks and polyhydroxystyrenes, are typically used in photoresist compositions. The production of film forming, novolak resins which may be used for preparing photosensitive compositions, are well known in the art. A procedure for the manufacture of novolak resins is described in Phenolic Resins, Knop A. and Pilato, L.; Springer Verlag, N.Y., 1985 in Chapter 5 which is incorporated herein by reference. The polyhydroxystyrene can be any polyhydroxystyrene, including single polymers of vinylphenol and polyhydroxystyrenes having protecting groups such as acetals, t-butoxycarbonyl, and t-butoxycarbonylmethyl; copolymers of vinylphenol and an acrylate derivative, acrylonitrile, a methacrylate derivative, methacrylonitrile, styrene, or a styrene derivative such as α-methylstyrene, p-methylstyrene, o-hydrogenated resins derived from single polymers of vinylphenol; and hydrogenated resins derived from copolymers of vinylphenol and the above-described acrylate derivative, methacrylate derivative, or styrene derivative. One such example of this class of polymer is described in U.S. Pat. No. 4,491,628, the contents of which are incorporated herein by reference.

The novolak resins typically comprise the addition-condensation reaction product of at least one phenolic compound with at least one aldehyde source. The phenolic compounds include for example cresols (including all isomers), xylenols (such as 2,4-, 2,5-xylenols, 3,5 xylenol, and tri-methyl phenol).

Aldehyde sources that can be used in this invention include formaldehyde, paraformaldehyde, trioxane, acetaldehyde, chloroacetaldehyde, and reactive equivalents of these aldehyde sources. Among these formaldehyde and paraformaldehyde are preferable. In addition mixtures of two or more different aldehydes can be used.

The acid catalyst used for the addition-condensation reaction includes hydrochloric acid, sulfuric acid, formic acid, acetic acid, oxalic acid, p-toluenesulfonic acid and the like.

The photoactive component (hereafter referred to as PAC) can be any compound known to be useful for use in photoresist compositions. Preferably it is diazonaphthoquinone sulfonate ester of a polyhydroxy compound or monohydroxy phenolic compound. Photoactive compounds can be prepared by esterification of 1,2-napthoquinonediazide-5-sulfonyl chloride and/or 1,2-naphthoquinonediazide-4-sulfonyl chloride with a phenolic compound or a polyhydroxy compound having 2-7 phenolic moieties, and in the presence of basic catalyst. The use of o-diazonaphthoquinones as photoactive compounds is well known to the skilled artisan. These sensitizers which comprise a component of the present invention are preferably substituted diazonaphthoquinone sensitizers, which are conventionally used in the art in positive photoresist formulations. Such sensitizing compounds are disclosed, for example, in U.S. Pat. Nos. 2,797,213, 3,106,465, 3,148,983, 3,130,047, 3,201,329, 3,785,825 and 3,802,885. Useful photosensitizers include, but are not limited to, the sulfonic acid esters made by condensing phenolic compounds such as hydroxy benzophenones, oligomeric phenols, phenols and their derivatives, novolaks and multisubstituted-multihydroxyphenyl alkanes with naphthoquinone-(1,2)-diazide-5-sulfonyl chloride or naphtho-quinone-(1,2)-diazide-4-sulfonyl chlorides. In one preferred embodiment monohydroxy phenols such as cumylphenol are preferred.

In another embodiment, preferably, the number of the phenolic moieties per one molecule of the polyhydroxy compound used as a backbone of PAC is in the range of 2-7, and more preferably in the range of 3-5.

Some representative examples of polyhydroxy compounds are:
(a) Polyhydroxybenzophenones such as 2,3,4-trihydroxybenzophenone, 2,4,4′-trihydroxybenzophenone, 2,4,6-trihydroxybenzophenone, 2,3,4-trihydroxy-2′-methylbenzophenone, 2,3,4,4′-tetrahydroxybenzophenone, 2,2′4,4′-tetrahydroxybenzophenone, 2,4,6,3′,4′-pentahydroxybenzophenone, 2,3,4,2′,4′-pentahydroxy-benzophenone, 2,3,4,2′,5′-pentahydroxybenzophenone, 2,4,6,3′,4′,5′-hexahydroxybenzophenone, and 2,3,4,3′,4′,5′-hexahydroxybenzophenone;
(b) Polyhydroxyphenylalkylketones such as 2,3,4-trihydroxyacetophenone, 2,3,4-trihydroxyphenylpentylketone, and 2,3,4-trihydroxyphenylhexylketone;
(c) Bis(polyhydroxyphenyl)alkanes such as bis(2,3,4-trihydroxyphenyl)methane, bis(2,4-dihydroxyphenyl)methane, and bis(2,3,4-trihydroxyphenyl)propane;
(d) Polyhydroxybenzoates such as propyl 3,4,5-trihydroxy-benzoate, phenyl 2,3,4-trihydroxybenzoate, and phenyl 3,4,5-trihydroxybenzoate;
(e) Bis(polyhydroxybenzoyl)alkanes or bis(polyhydroxybenzoyl)aryls such as bis(2,3,4-trihydroxybenzoyl)methane, bis(3-acetyl-4,5,6-trihydroxyphenyl)methane, bis(2,3,4-trihydroxybenzoyl)benzene, and bis(2,4,6-trihydroxybenzoyl)benzene;
(f) Alkylene di(polyhydroxybenzoates) such as ethylene glycol-di(3,5-dihydroxybenzoate) and ethylene glycoldi(3,4,5-trihydroxybenzoate);
(g) Polyhydroxybiphenyls such as 2,3,4-biphenyltriol, 3,4,5-biphenyltriol, 3,5,3′5′-biphenyltetrol, 2,4,2′,4′-biphenyltetrol, 2,4,6,2′,4′,6′-biphenylhexyl, and 2,3,4,2′,3′,4′-biphenylhexyl;
(h) Bis(polyhydroxy)sulfides such as 4,4′-thiobis(1,3-dihydroxy)benzene;
(i) Bis(polyhydroxyphenyl)ethers such as 2,2′4,4′-tetrahydroxydiphenyl ether;
(j) Bis(polyhydroxyphenyl)sulfoxides such as 2,2′,4,4′-tetrahydroxydiphenylsulfoxide;
(k) Bis(polyhydroxyphenyl)sulfones such as 2,2′,4,4′-tetrahydroxydiphenylsulfone;
(l) Polyhydroxytriphenylmethanes such as tris(4-hydroxyphenyl)methane), 4,4′,4″-trihydroxy-3,5,3′,5′-tetramethyltriphenylmethane, 4,4′,3″,4″-tetrahydroxy-3,5,3′,5′-tetramethyltriphenylmethane, 4,4′,2″,3″,4″-pentahydroxy-3,5,3′,5′-tetramethyltriphenylmethane, 2,3,4,2′,3′,4′-hexahydroxy-5,5′-diacetyltriphenylmethane, 2,3,4,2′,3′,4′,3″,4″-octahydroxy-5,5-diacetyltriphenylmethane, and dipropionyltriphenylmethane;
(m) Polyhydroxy-spirobi-indanes such as 3,3,3′,3′-tetramethyl-1,1′-spirobi-indane-5,6,5′,6′-tetrol, 3,3,3′3′-tetramethyl-1,1′-spirobi-indane-5,6,7,6′6′,7′-hexyl, and 3,3,3′3′-tetramethyl-1,1′-spirobi-indane-4,5,6,4′,5′,6′-hexyl;
(n) Polyhydroxyphthalides such as 3,3-bis(3,4-dihydroxyphenyl)phthalide, 3,3-bis(2,3,4-trihydroxyphenyl)phthalide, and 3′,4′,5′,6′-tetrahydroxyspiro(phthalide-3,9′-xanthene);
(o) Polyhydroxy compounds described in JP No. 4-253058 such as α,α′,α″-tris(4-hydroxyphenyl)-1,3,5-triisopropylbenzene, α,α′,α″-tris(3,5-dimethyl-4-hydroxyphenyl)-1,3,5-triisopropylbenzene, α,α′,α″-tris(3,5-diethyl-4-hydroxyphenyl)-1,3,5-triisopropylbenzene, α,α′,α″-tris(3,5-di-n-propyl-4-hydroxyphenyl)-1,3,5-tri-isopropylbenzene, α,α′,α″-tris(3,5-diisopropyl-4-hydroxyphenyl)-1,3,5-triisopropylbenzene, α,α′,α″-tris(3,5-di-n-butyl-4-hydroxyphenyl)-1,3,5-triisopropylbenzene, α,α′,α″-tris(3-methyl-4-hydroxyphenyl)-1,3,5-triisopropyl-benzene, α,α′,α″-tris(3-methoxy-4-hydroxyphenyl)-1,3,5-triisopropylbenzene, α,α′,α″-tris(2,4-dihydroxyphenyl)-1,3,5-triisopropylbenzene, 2,4,6-tris(3,5-dimethyl-4-hydroxyphenylthiomethyl)mesitylene, 1-[α-methyl-α-(4″-hydroxyphenyl)ethyl]-4-[α,α′-bis(4″-hydroxyphenyl)ethyl]benzene, 1-[α-methyl-α-(4′-hydroxyphenyl)ethyl]-3-[α,α′-bis(4″-hydroxy-phenyl)ethyl]benzene, 1-[α-methyl-α-(3′,5′-dimethyl-4′-hydroxyphenyl)ethyl]benzene, 1-[α-methyl-α-(3′-methoxy-4′-hydroxyphenyl)ethyl]-4-[α′,α′-bis(3′-methoxy-4′-hydroxyphenyl)ethyl]benzene, and 1-[α-methyl-α-(2′,4′-dihydroxyphenyl)ethyl]-4-[α′,α′-bis(4′-hydroxyphenyl)ethyl]-benzene.

Other examples of o-quinonediazide photoactive compounds include condensation products of novolak resins with an o-quinonediazide sulfonyl chloride. These condensation products (also called capped novolaks) may be used instead of o-quinonediazide esters of polyhydroxy compounds or used in combination therewith. Numerous U.S. patents describe such capped novolaks. U.S. Pat. No. 5,225,311 is one such example. Mixtures of various quinone-diazide compounds may also be used.

Suitable examples of the acid generating photosensitive compounds include, without limitation, ionic photoacid generators (PAG), such as diazonium salts, iodonium salts, sulfonium salts, or non-ionic PAGs such as diazosulfonyl compounds, sulfonyloxy imides, and nitrobenzyl sulfonate esters, although any photosensitive compound that produces an acid upon irradiation may be used. The onium salts are usually used in a form soluble in organic solvents, mostly as iodonium or sulfonium salts, examples of which are diphenyliodonium trifluoromethane sulfonate, diphenyliodonium nonafluorobutane sulfonate, triphenylsulfonium trifluoromethane sulfonate, triphenylsulfonium nonafluorobutane sulfonate and the like. Other compounds that form an acid upon irradiation that may be used are triazines, oxazoles, oxadiazoles, thiazoles, and substituted 2-pyrones. Phenolic sulfonic esters, bis-sulfonylmethanes, bis-sulfonylmethanes or bis-sulfonyldiazomethanes, triphenylsulfonium tris(trifluoromethylsulfonyl)methide, triphenylsulfonium bis(trifluoromethylsulfonyl)imide, diphenyliodonium tris(trifluoromethylsulfonyl)methide, diphenyliodonium bis(trifluoromethylsulfonyl)imide and their homologues are also possible candidates.

Examples of photoresist compositions based on film-forming resins having acid labile groups and photoacid generators are described, for example, in U.S. Pat. No. 6,447,980, the contents of which is incorporated herein by reference.

Generally, film-forming resins include those of the general formula

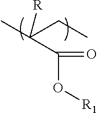

where R is hydrogen or C₁-C₄ alkyl and R₁ is an acid liable group, as well as

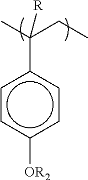

where R is as defined above and R₂ is hydrogen or an acid labile group, wherein the phenolic hydroxyl group is partially or fully protected by an acid labile group, preferably by one or more protective groups which form acid cleavable C—O—C or C—O—Si bonds. For example, and without limitation, include acetal or ketal groups formed from alkyl or cycloalkyl vinyl ethers, silyl ethers formed from suitable trimethylsilyl or t-butyl(dimethyl)silyl precursors, alkyl ethers formed from methoxymethyl, methoxyethoxymethyl, cyclopropylmethyl, cyclohexyl, t-butyl, amyl, 4-methoxybenzyl, o-nitrobenzyl, or 9-anthrylmethyl precursors, t-butyl carbonates formed from t-butoxycarbonyl precursors, and carboxylates formed from t-butyl acetate precursors, and t-butoxycarbonylmethyl.

Additional film forming resins are also disclosed in U.S. Pat. No. 7,211,366, the contents of which are hereby incorporated by reference herein.

In situations where the composition uses a dissolution inhibitor, R₁ in the above formula need not be an acid labile group. As is well known in the art, an acid labile group reflects those groups which are resistant to basic conditions but are removable under acidic conditions.

Other types of resin binders suitable for use in the positive photoresist composition include those disclosed in U.S. Pat. No. 4,491,628 and U.S. Pat. No. 6,358,665, the contents thereof are hereby incorporated herein by reference.

Another component of the novel positive photoresist composition is an inorganic particle material. The inorganic particle is one which increases the dry etch resistance of the coating in plasma gases, such as those comprising chlorine. Suitable inorganic particle materials which can be used include metals, metal salts, metallic oxides, and combinations thereof. Suitable metals are such as those in Groups VIIB, VIIB, VIIIB, IB, IIB, IIA, IVA, VA, VIA of the periodic table of elements and combinations thereof, Suitable examples of metals include titanium, vanadium, cobalt, hafnium, boron, gold, silver, silicon, aluminum, copper, zinc, gallium, magnesium, indium, nickel, germanium, tin, molybdenum, niobium, zirconium, platinum, palladium, antimony, and combinations thereof. Suitable examples of metal salts include halides, carbides and nitrides of the above metals, such as silicon carbide, silicon nitride and combinations thereof. Examples of metallic oxides include those available from the Groups mentioned above and combinations thereof. Suitable examples include magnesium oxide, iron (III) oxide, aluminum oxide, chromium oxide, zinc oxide, titanium dioxide, silicon dioxide and combinations thereof. Specifically, metal oxides may be used; silicon dioxide as an example may be used as the nanoparticle. In general, the average particle size (diameter) of the inorganic particle is between about 1 and 100 nm, further between about 10 and about 50 nm, and further between about 10 and about 15 nm. Such particles may be spherical.

Typically the percentage content of the inorganic particle material is between about 0.1% and about 90% by weight of the photosensitive composition; further between about 5% and about 75% and further between about 10% and about 50% by weight and even further between about 10% and about 30% by weight.

In useful embodiments, when the inorganic particle material is added to a photoresist composition, it has been unexpectedly discovered that the combination of the inorganic particle material and positive photoresist allows for the formation of thin photosensitive films with good lithographic properties and high dry etch resistance.

Typically, the thickness of the photosensitive composition containing inorganic particle material on a substrate is between about 0.5 to about 5 μm, further between about 1 and about 4 μm, further between about 2 and about 4 μm, and even further between about 3 μm and 4 μm or between about 1 and about 2 μm.

For example, colloidal silica (SiO₂) can be prepared in 1 to 100 nm diameter particles, and is commercially available as 8-10 nm, 10-15 nm, 10-20 nm, 17-23 nm, and 40-50 nm particles. Such colloidal silicas are available from, for example, Nissan Chemicals. In some instances, the colloidal silicas are supplied in various solvents which are not very useful in the photoresist area. In most instances, it is beneficial to disperse the colloidal silica in a solvent which is useful, for example, propylene glycol mono-methyl ether, propylene glycol mono-methyl ether acetate, ethyl lactate, etc.

In the preferred embodiment, the solid parts of the photosensitive composition preferably range from 95% to about 40% resin with from about 5% to about 50% photoactive component. A more preferred range of resin would be from about 50% to about 90% and most preferably from about 65% to about 85% by weight of the solid photosensitive components. A more preferred range of the photoactive component would be from about 10% to about 40% and most preferably from about 15% to about 35%, by weight of the solid in the photosensitive composition.

Other additives such as colorants, non-actinic dyes, plasticizers, adhesion promoters, coating aids, sensitizers, crosslinking agents, surfactants, and speed enhancers may be added to the photosensitive composition suitable for image-wise exposure and development as a positive photoresist before the solution is coated onto a substrate. The type of surfactant to be added include nonionic based surfactants such as fluorinated and silicone containing surfactants, alkyl ethoxylated surfactants, block copolymer surfactants, and sorbitan ester surfactants as well as those well known to those skilled in the art. Other examples include alkyl alkoxylated surfactant, such as addition products of ethylene oxide, or propylene oxide, with fatty alcohols, fatty acids, fatty amines, etc.

Suitable solvents for photoresists may include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate; carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof.

The prepared novel photosensitive composition solution can be applied to a substrate by any conventional method used in the photoresist art, including dipping, spraying, whirling and spin coating. When spin coating, for example, the resist solution can be adjusted with respect to the percentage of solids content, in order to provide coating of the desired thickness, given the type of spinning equipment utilized and the amount of time allowed for the spinning process. Suitable substrates include, without limitation, silicon, aluminum, polymeric resins, silicon dioxide, metals, doped silicon dioxide, silicon nitride, tantalum, copper, polysilicon, ceramics, sapphire, aluminum/copper mixtures; gallium arsenide, SiC, GaN, and other such Group III/V compounds.

The novel photosensitive coatings produced by the described procedure are particularly suitable for application to substrates such as those which are utilized in the production of microprocessors and other miniaturized integrated circuit components. The substrate may also comprise various polymeric resins, especially transparent polymers such as polyesters. The substrate may have an adhesion promoted layer of a suitable composition, such as one containing hexa-alkyl disilazane.

The novel photosensitive composition solution is then coated onto the substrate, and the substrate is treated at a temperature from about 50° C. to about 200° C. for from about 30 seconds to about 6 minutes (or even longer) on a hot plate or for from about 15 to about 90 minutes (or even longer) in a convection oven. This temperature treatment is selected in order to reduce the concentration of residual solvents in the photoresist, while not causing substantial thermal degradation of the photosensitizer. In general, one desires to minimize the concentration of solvents and this first temperature treatment is conducted until substantially all of the solvents have evaporated and a coating of photoresist composition, on the order of 1-5 microns (micrometer) in thickness, remains on the substrate. In a preferred embodiment the temperature is from about 95° C. to about 135° C. The temperature and time selection depends on the photoresist properties desired by the user, as well as the equipment used and commercially desired coating times. The coating substrate can then be exposed to actinic radiation, e.g., ultraviolet radiation, at a wavelength of from about 157 nm (nanometers) to about 450 nm, x-ray, electron beam, ion beam or laser radiation, as well as other sub-200 nm wavelengths, in any desired pattern, produced by use of suitable masks, negatives, stencils, templates, etc. Generally, photoresist films of the present invention are exposed using broadband radiation, using equipments such as Ultratech, Karl Suss or Perkin Elmer broadband exposure tools, although 436 nm, 365 nm, and 248 nm stepper exposure tools may also be used.

The photoresist is then optionally subjected to a post exposure second baking or heat treatment either before or after development. The heating temperatures may range from about 90° C. to about 150° C., more preferably from about 100° C. to about 140° C. The heating may be conducted for from about 30 seconds to about 3 minutes, more preferably from about 60 seconds to about 2 minutes on a hot plate or about 30 to about 45 minutes by convection oven.

The exposed photoresist-coated substrates are developed to remove the image-wise exposed areas by immersion in a developing solution or developed by spray development process. The solution is preferably agitated, for example, by nitrogen burst agitation. The substrates are allowed to remain in the developer until all, or substantially all, of the photoresist coating has dissolved from the exposed areas. Developers include aqueous solutions of ammonium or alkali metal hydroxides. One preferred hydroxide is tetramethyl ammonium hydroxide. Other preferred bases are sodium or potassium hydroxide. Additives, such as surfactants, may be added to the developer. After removal of the coated wafers from the developing solution, one may conduct an optional post-development heat treatment or bake to increase the coating's adhesion and density of the photoresist. The imaged substrate may then be coated with metals, or layers of metals to form bumps as is well known in the art, or processed further as desired. In a typical PSS LED fabrication processes, wet or dry etch processes can be applied, where the patterned photoresist substrates are subjected to wet or dry etching; Buffered Oxide Etch:H₃PO₄/H₂SO₄ etch in wet etch processes or chlorine containing gases like BCl₃/Cl₂ by reactive ion etch (RIE) in a dry etch process. In these processes the photoresist serves as the etch mask for underlying substrates used in LED fabrication to achieve the desired etched patterns, such as sapphire surface texture roughening or MESA GaN opening for subsequent metal contacts formation.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

### Silica Nanoparticles

Silica nanoparticles in ethylene glycol mono-n-propyl ether (NPC-ST-30, 10-15 nm in diameter, Snowtex, manufactured by Nissan Chemical America Corporation, 10375 Richmond Avenue Suite 1000, Houston, Tex., a solid matter content of silica of 30-31% by weight was used in the experiment.

### Formulation Example 1

### Preparation of Positive Nanocomposite Photoresists from AZ® GXR 601

Five solutions were prepared adding the NPC-ST-30 silica colloidal solution into AZ® GXR601 (from AZ® Electronic Materials USA Corp., 70 Meister Ave., Somerville, N.J. (a novolak polymer/diazonaphthoquinone diazide) photoresist in propylene glycol mono-methyl ether acetate with a solid content of 30.6% by weight), as shown in Table 1. The solutions were rolled overnight at room temperature and used without filtration. The solutions were transparent and the silica content was 30-70% by weight (solid matter base). The solvent content in the nanocomposite photoresists was about 69.3% by weight. The silica nanoparticles were incorporated into the polymer matrices homogeneously without agglomeration. No precipitation was observed after 3 months.

TABLE 1

| | GXR601 | NPC-ST-30 | Silica content in solid |
|---|---|---|---|
| | (g) | (g) | (%, by weight) |
| Sample 1 | 10 | 0 | 0 |
| Sample 2 | 10 | 4.5 | 30 |
| Sample 3 | 10 | 6.6 | 40 |
| Sample 4 | 10 | 10 | 50 |
| Sample 5 | 10 | 15 | 60 |
| Sample 6 | 10 | 23 | 70 |

### Formulation Example 2

### AZ12XT: Diluted AZ® 12XT-20PL-5

Commercial AZ® 12XT-20PL-5 (solid content 30% by weight), available from AZ® Electronic Materials USA Corp. (novolak capped with acid labile/NIT in PGMEA) was diluted in PGMEA solvent by rolling over night. This dilution was done to enable this photoresist, normally for thick film application, to be applied as a 2 micron thick film. This diluted version of AZ® 12XT-20PL-5 was named AZ12XT.

### Formulation Example 3

### AZ® 12XT-NC Positive Nanocomposite Photoresist

A solution was prepared by adding 12.9 g of the NPC-ST-30 silica colloidal solution into 20 g of AZ® 12XT-20PL-5 (from AZ® Electronic Materials USA Corp.) to give a 40% by weight solids of silica. The solution was rolled overnight at room temperature and used without filtration. The solution was transparent. This formulation was named AZ® 12XT-NC and used for lithographic comparison as reported below. The silica nanoparticles formulated into AZ® 12XT were incorporated into the polymer matrices homogeneously without agglomeration. No precipitation was observed after 3 month. Similarly, other versions of this resist were prepared with 20 and 30% by weight silica by varying the amount of NPC-ST-30 solution employed and these were used in the etching studies reported below.

### Lithography Example 1

The photoresist solutions from Table 1 were coated onto 6 inch silicon wafers and baked at 90° C. for 90 seconds to give a coating of 2 μm. The wafers were exposed on an ASML i-line stepper(NA=0.54, σ=0.75, focus). The post exposure bake conditions were 110° C. for 60 seconds. The wafers were then developed in AZ® 300 MIF developer at 23° C. using a 60 second puddle for sample 1 or a 20 or 30 second puddle for samples 2 to 6.

The nanocomposite resists exhibited good photospeed, good resolution and straight profiles. When silica nanoparticles were dispersed homogeneously in polymer matrices, the polymer provided a protective layer which retarded dissolution of silica in the unexposed parts. On the other hand, hydroxyl groups on the surface of silica nanoparticles (the hydrophilic surface) contributed to the high dissolution rate in the exposed parts.

Comparison of Sample 1 (GXR 601) to Sample 2(GXR 601 with 30% SiO₂)

The resolution dose of 1 micron dense lines for sample 2 (80 mJ/cm²) was somewhat lower to that found for Sample 1 (110 mJ/cm²). Sample 2 had a bit more of a tendency to foot as the feature size resolved decreases down to 0.75 μm. In terms of depth of focus for 1.0 μm dense features Sample 1 has a depth of focus of ˜1.6 μm while Sample 2 has a larger tendency to foot giving it a depth of focus of ˜1.4 μm. The dose latitude of 1 micron lines for Sample 2 containing the SiO₂ particles is somewhat less ˜13% compared to that of the resist alone Sample 1 (19%), due to a slightly higher tendency for footing for Sample 1.

Overall, the development of the 2 samples gave acceptable pattern profiles, showing that addition of nanoparticles to the photoresist did not degrade the lithographic performance.

### Lithographic Example 2

### Lithography Performance of AZ® 12XT-NC (with SiO₂ Nanoparticles) Compared to AZ® 12XT (Without SiO₂ Nanoparticles)

The photoresist solution AZ® 12XT and AZ® 12XT-NC—from formulation example 2 and 3 were coated onto 6 inch silicon wafers at a spin speed of 1900 rpm and 1700 rpm respectively and baked at 90° C. for 60 seconds to give a coatings of 2 μm. The wafers were exposed on an ASML i-line stepper (NA=0.48, σ=0.75, focus). The post exposure bake conditions were 110° C. for 30 seconds for AZ® 12XT-20PL-5 and 90° C. for 30 seconds for AZ® 12XT-NC. The wafers were then developed in AZ® 300 MIF developer at 23° C. using two 30 second puddles.

The nanocomposite in both resist exhibited fast photospeed and good resolution. When silica nanoparticles were dispersed homogeneously in polymer matrices, the polymer provided a protective layer which retarded dissolution of silica in the unexposed parts. On the other hand, hydroxyl groups on the surface of silica nanoparticles (the hydrophilic surface) contributed the high dissolution rate in the exposed parts. In this manner lines and spaces (Line/Space=1/1) could be resolved down to 0.8 microns and posts (Post/space=1/1) down to 0.9 microns for AZ® 12XT-NC. Overall, the development of the 2 samples gave acceptable pattern profiles, showing that addition of nanoparticles to the photoresist did not degrade the lithographic pattern formation performance.

### Resistance to Plasma Etching.

Plasma etch was carried out in a NE-5000N etcher produced by Alvac Co. The plasma etch resistance of a photoresist was evaluated by the decreased thickness of film thickness after the etching treatment. Nanospec 8000 film thickness measurement system was used to determine the film thickness. The Cl₂/BCl₃/Ar etching was performed at a pressure of 0.6 Pa, with antenna power of 750 W and bias power of 50 W, and Cl₂ flow of 40 SCCM, BCl₃ flow of 13 SCCM and Ar flow of 13 SCCM.

### Plasma Etching Example 1

Table 2 summarizes the etch data for samples of AZ® GXR601 containing different % of SiO₂ where it can be seen that the etch rate decreases concurrent with increased loading of SiO₂ nanoparticles. Similarly, the normalized etch rate under the same conditions as a function of the SiO₂ nanoparticle loading in GXR601.

This Table 2 also gives a comparison of the relative etch rate of these resists to the Sapphire substrate itself. It is observed that as the silica content increases the etch selectivity steadily improves, thus increasing the silica content makes the photoresist more etch resistant.

TABLE 2
Etching selectivity of Sapphire/GXR601-NC resist

| | Silica (%) | | | | | |
|---|---|---|---|---|---|---|
| | 0 | 30 | 40 | 50 | 60 | 70 |
| FT change (um) | 0.2865 | 0.2735 | 0.2541 | 0.24 | 0.2158 | 0.188 |
| Etch rate in A/min | 955 | 912 | 847 | 800 | 719 | 627 |
| Normalized rate | 1 | 0.955 | 0.887 | 0.838 | 0.753 | 0.656 |
| Sapphire selectivity | 0.62 | 0.591867 | 0.549885 | 0.519372 | 0.467002 | 0.406841 |
| per 1 um FT resist | | | | | | |

### Plasma Etching Example 2

Table 3 gives a comparison of the absolute and normalized etching rates for formulations based on AZ® 12XT-NC with different loadings of silica nanoparticles spun as 2 micron films. AZ® 12XT formulated with silica gives a much slower etching rate in proportion to the amount of silica nanoparticles employed. It can be seen that AZ® 12-XT-NC formulated with 40% silica nanoparticles gives a much slower etching rates under plasma etching conditions, typically used for etching Sapphire.

TABLE 3
Plasma Etch Results Comparison of AZ ® 12-XT (0% silica) with
AZ ® 12-XT-NC with different loading of silica (20, 30 and 40%)

| Silica (%) | 0 | 20 | 30 | 40 |
|---|---|---|---|---|
| FT change | 0.236 | 0.2328 | 0.2224 | 0.205 |
| (um) | | | | |
| Etch rate | 787 | 776 | 741 | 683 |
| in A/min | | | | |
| Normalized | 1 | 0.986 | 0.942 | 0.868 |
| rate | | | | |

Finally, Table 4 compares sapphire etch selectivity for the two positive resists in our examples at a 40% silica loading using the GXR 601 as a benchmark. As can be seen, in both cases the resists etch more slowly than the Sapphire substrate itself.

TABLE 4
Etching selectivity of Sapphire/resist

| Sample ID (40% | | | |
|---|---|---|---|
| silica) | GXR 601 | GXR 601-NC | 12XT-NC |
| Normalized etch rate | 1 | 0.887 | 0.868 |
| Sapphire selectivity | 0.62 | 0.54994 | 0.53816 |
| per 1 um FT resist | | | |

1. A positive photosensitive composition comprising a positive photoresist composition and an inorganic colloidal particle material having an average particle diameter equal or less than 100 nanometers, wherein the thickness of the photosensitive coating film is less than 5 microns.

2. The positive photosensitive composition of claim 2 wherein the positive photoresist composition is (1) a composition comprising (i) a film-forming resin having acid labile groups, and (ii) a photoacid generator.

3. The positive photosensitive composition of claim 2 wherein the positive photoresist composition is (2) a composition comprising (i) a film-forming novolak resin, and (ii) a photoactive compound.

4. The positive photoresist composition of claim 2 wherein the positive photoresist composition is (3) a composition comprising (i) a film-forming resin, (ii) a photoacid generator, and (iii) a dissolution inhibitor.

5. The positive photosensitive composition according to claim 1, where the film has a thickness less than 4 microns.

6. The positive photosensitive composition according to claim 1, where the film has a thickness less than 3 microns.

7. The positive photosensitive composition according to claim 1, where the film has a thickness less than 2 microns.

8. The positive photosensitive composition according to claim 1, where the inorganic particle material is selected from a group consisting of colloidal silica, colloidal copper and colloidal TiO₂.

9. The positive photosensitive composition according to claim 1, where the inorganic colloidal particle material is SiO₂.

10. The positive photosensitive composition according to claim 1, where the inorganic particle material is SiO₂ and has an average particle size from about 5 to about 100 nanometers.

11. The positive photosensitive composition according to claim 1, where the inorganic particle material has an average particle size from about 10 to about 15 nanometers.

12. The positive photosensitive composition according to claim 1, where the inorganic particle material is present in an amount of from about 0.1% and about 90% by weight of the photosensitive composition.

13. The positive photosensitive composition according to claim 1, where the inorganic particle material is present in an amount of from about 5% and about 75% by weight of the photosensitive composition.

14. The positive photosensitive composition according to claim 1, where the inorganic particle material is present in an amount of from about 10% and about 50% by weight of the photoresist.

15. The positive photosensitive composition according to claim 1, where the inorganic particle material is present in an amount of from about 10% and about 30% by weight of the photoresist.

16. A process for forming a positive photoresist image on a substrate, comprising the steps of:
a) coating the photoresist composition of claim 1 on a substrate, thereby forming a photoresist coating film with a thickness less than 5 microns;
b) imagewise exposing the coated substrate to radiation;
c) developing the exposed substrate to form a photoresist image; and,
d) etching the substrate with a gas comprising chlorine, thereby forming a roughened substrate.

17. The process claim according to claim 16 where the substrate is selected from sapphire, SiC and GaN.
